(19) United States
(12) Patent Application Publication
(10) Pub. No.: US 2025/0359378 A1
(43) Pub. Date: Nov. 20, 2025

(54) IMAGE SENSOR STRUCTURE FOR CROSSTALK REDUCTION

(71) Applicant: Taiwan Semiconductor Manufacturing Company, Ltd., Hsinchu (TW)

(72) Inventors: Wei Chih Huang, Hsinchu (TW); Shuang-Ji Tsai, Tainan City (TW); Hsing-Chih Lin, Tainan City (TW); Jen-Cheng Liu, Hsinch-Chu City (TW); Dun-Nian Yaung, Taipei City (TW)

(21) Appl. No.: 19/279,824

(22) Filed: Jul. 24, 2025

Related U.S. Application Data
(62) Division of application No. 17/892,820, filed on Aug. 22, 2022.
(60) Provisional application No. 63/336,851, filed on Apr. 29, 2022.

(51) Int. Cl. H10F 39/00; H10F 39/12; H10F 39/18

(52) U.S. Cl. CPC H10F 39/807; H10F 39/014; H10F 39/182; H10F 39/199; H10F 39/8053; H10F 39/8057; H10F 39/8063

(57) ABSTRACT

Image sensors and processes of forming the same are provided. An image sensor according to the present disclosure includes a first photodiode disposed between a second photodiode and a third photodiode along a direction, a first deep trench isolation (DTI) feature disposed between the first photodiode and the second photodiode, and a second DTI feature disposed between the first photodiode and the third photodiode. A depth of the first DTI feature is greater than a depth of the second DTI feature. A quantum efficiency of the second photodiode is smaller than a quantum efficiency of the first photodiode.

### PRIORITY DATA

This application is a divisional application of U.S. patent application Ser. No. 17/892,820, filed Aug. 22, 2022, which claims benefits of U.S. Provisional Patent Application Ser. No. 63/336,851, filed Apr. 29, 2022, each of which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Image sensors, such as complementary metal-oxide-semiconductor (CMOS) image sensors (CIS), are frequently found in modern-day consumer electronics. For example, CIS is heavily used to realize automation and sensory functions in the automobile industry. To enhance image detection sensitivity, photodiodes of different sizes may be implemented in an array. Because photodiodes of different sizes have different quantum efficiency (QE) levels, crosstalk from large photodiodes may result in substantial noise in neighboring small photodiodes. Therefore, while existing image sensor structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of fabricating an image sensor device according to various aspects of the present disclosure.

FIGS. 2-19 illustrate diagrammatic fragmentary cross-sectional views or top views of a workpiece undergoing various stages of fabrication according to the method of FIG. 1, according to various aspects of the present disclosure.

FIG. 20 illustrates an example reference structure, according to various aspects of the present disclosure.

FIG. 21 schematically illustrates how various features of the image sensor of the present disclosure operate to reduce crosstalk, according to various aspects of the present disclosure.

FIGS. 22 and 23 illustrate schematical top views of opening(s) for metal absorber features relative to a small photodiode region, according to various aspects of the present disclosure.

FIGS. 24-27 illustrate fragmentary top views of image sensors where extended deep trench isolation (DTI) features are implemented around small photodiodes, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Complementary metal-oxide-semiconductor (CMOS) image sensors (CIS) have gained popularity in recent years. For example, CIS is used to realize automation and sensory functions in the automobile industry. When serving those functions, CIS provides machine vision to aid or replace human vision. One challenge faced by the industry is light-emitting-diode (LED) flickering, which can be extremely distracting for machine vision. One of the solutions is a split pixel technology that implements both large photodiodes and small photodiodes. Large photodiodes have greater quantum efficiency (QE) than small photodiodes. In some examples, large photodiodes have larger size or different implant dopants to have greater QE. That said, large photodiodes are not necessarily larger than small photodiodes. The large photodiodes are configured to capture the scene in a short exposure time and small photodiodes are configured to capture LED signals in a long exposure time. When a split pixel technology or a similar technology is adopted, large photodiode and small photodiodes may be disposed next to one another. Light from a neighboring large photodiode may cause noise in a small photodiode. Light from a large photodiode may cross into a small photodiode through gaps of deep trench isolation (DTI) features, through reflection from back-end-of-line metal features, or through micro lens and color filter.

The present disclosure provides an image sensor structure that reduces crosstalk between large photodiodes and small photodiodes. In one aspect, the image sensor structure of the present disclosure implements deeper or extended deep trench isolation (DTI) features around small photodiodes to better block light noise from neighboring large photodiodes. In another aspect, the image sensor structure of the present disclosure includes a metal film buried in a passivation structure over a small photodiode to block light noise from overlying micro lens and color filter. In still another aspects, the image sensor structure of the present disclosure includes a contact structure in the back-end-of-line (BEOL) structure to block light noise reflected from metal features. The various features of the present disclosure may function alone or in combination to reduce cross talk to small photodiodes.

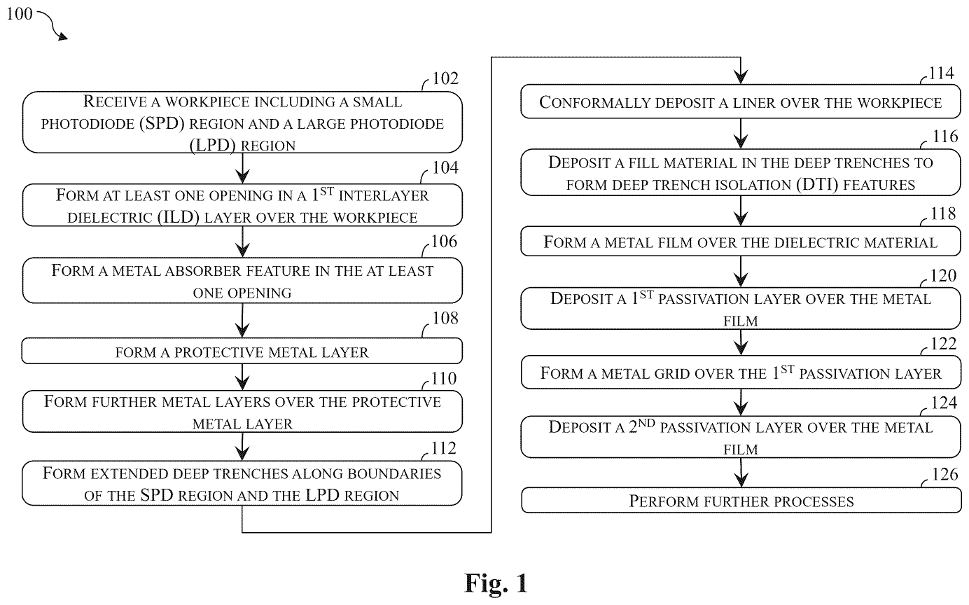

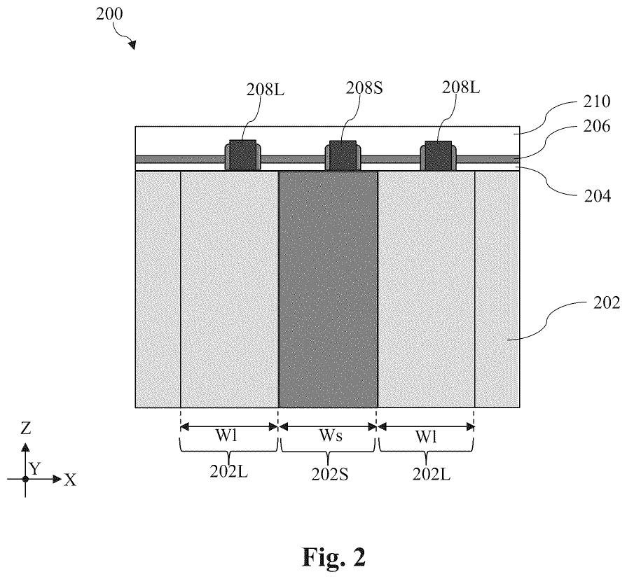

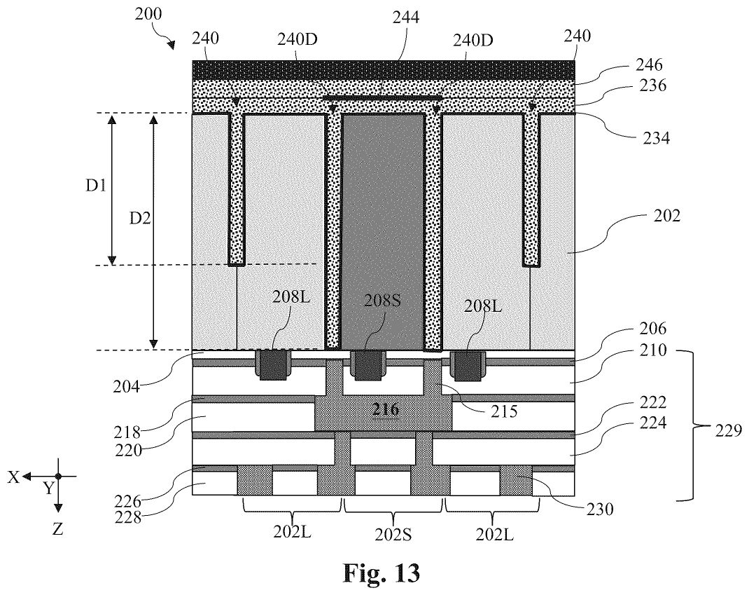

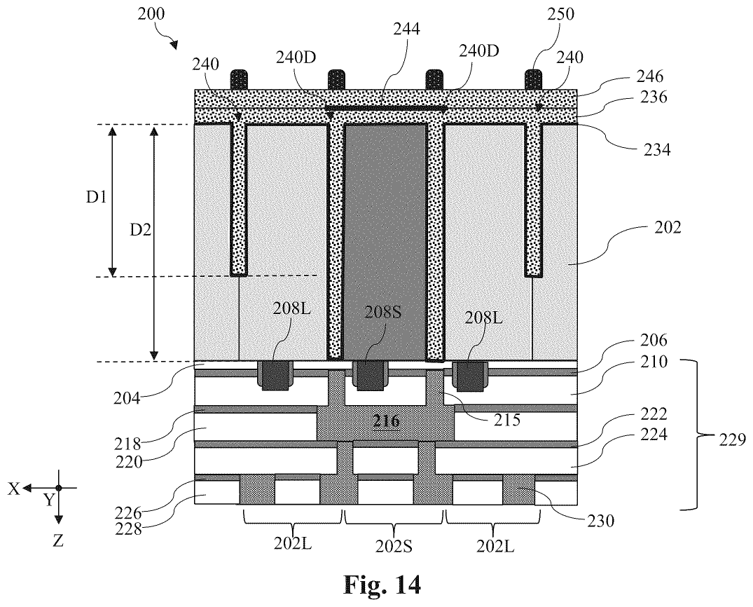

The various aspects of the present disclosure will now be described in more detail with reference to the figures. In that regard, FIG. 1 is a flowchart illustrating method 100 of forming an image sensor on a workpiece 200 according to embodiments of the present disclosure. Method 100 is merely an example and is not intended to limit the present disclosure to what is explicitly illustrated in method 100. Additional steps may be provided before, during and after the method 100, and some steps described can be replaced, eliminated, or moved around for additional embodiments of the method. Not all steps are described herein in detail for reasons of simplicity. Method 100 is described below in conjunction with FIGS. 2-19, which are fragmentary cross-sectional views a workpiece 200 at different stages of fabrication according to embodiments of method 100. Because the workpiece 200 will be fabricated into an image sensor or an image sensor structure at the conclusion of the fabrication processes, the workpiece 200 may also be referred to as an image sensor 200 or an image sensor structure 200 as the context requires. Additionally, throughout the present application, like reference numerals denote like features, unless otherwise excepted. The X, Y and Z directions are used consistently in FIGS. 2-16 and are perpendicular to one another.

Referring to FIGS. 1 and 2, method 100 includes a block 102 where a workpiece 200 that includes a small photodiode (SPD) region 202S and a large photodiode (LPD) region 202L is received. As shown in FIG. 2, the workpiece 200 includes a substrate 202 that is divided into small photodiode (SPD) regions 202S and large photodiode (LPD) regions 202L. The workpiece 200 further includes LPD transistors 208L fabricated over the LPD regions 202L and SPD transistors 208S fabricated over the SPD regions 202S. The LPD transistors 208L and SPD transistors 208S are isolated from one another by an isolation feature 204. The workpiece 200 further includes a first etch stop layer 206 over the isolation feature 204 and a first interlayer dielectric (ILD) layer 210. The substrate 202 may be a bulk silicon (Si) substrate. Alternatively, substrate 202 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

To form the SPD regions 202S and LPD regions 202L in the substrate 202, the substrate 202 can include various doped regions (not shown), such as p-type doped regions, n-type doped regions, or combinations thereof. In one embodiment, the substrate 202 may include p-type dopants, such as boron (B), boron difluoride (BF2), or other p-type dopants as well as n-type dopants, such as phosphorus (P), arsenic (As), or other n-type dopants. In this embodiment, the substrate 202 may be a commercially available silicon substrate with p-type dopants and n-type dopants introduced to certain regions of the substrate 202 in order to form image sensors, which may also be referred to as photodiodes.

Each of the SPD transistors 208S and the LPD transistors 208L includes a source, a drain, a channel region disposed between the source and drain, and a gate structure over the channel region. It is noted that the SPD transistors 208S and the LPD transistors 208L shown in FIG. 2 may represent transistor of different configurations. For example, the they may be planar transistors, fin-type field effect transistors (finFETs), multi-bridge-channel (MBC) transistors, gate-all-around (GAA) transistors, nanowire transistors, nanosheet transistors, transistors with nanostructures, or other multi-gate transistors where the gate structure engages more than one surfaces of the channel region. Active regions of the SPD transistors 208S and the LPD transistors 208L are isolated from one another by the isolation feature 204, which may be shallow trench isolation (STI) features. Depending on the configuration of the SPD transistors 208S and the LPD transistors 208L, their active regions may be embedded the isolation feature 204, have a sheet-like shape, a fin-like shape, or may include a plurality of channel members vertically spaced apart from one another. The isolation feature 204 may include silicon oxide, silicon nitride, silicon oxynitride, fluorine-doped silicate glass (FSG), a low-k dielectric, combinations thereof, and/or other suitable materials. The first etch stop layer 206 may include silicon nitride or silicon oxynitride. The first ILD layer 210 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

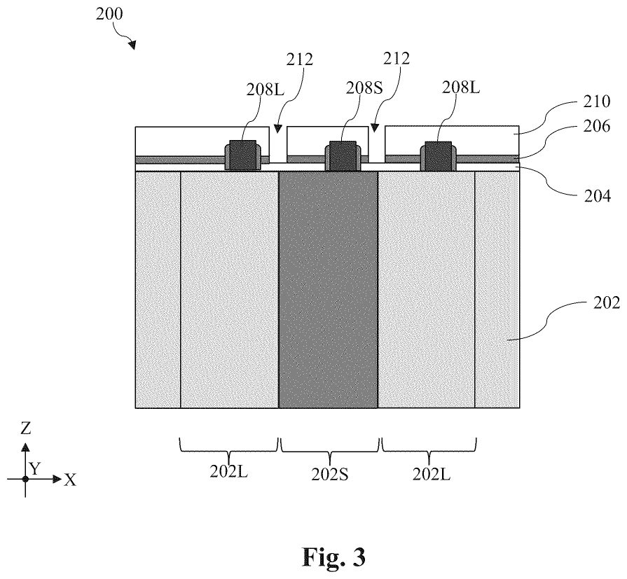

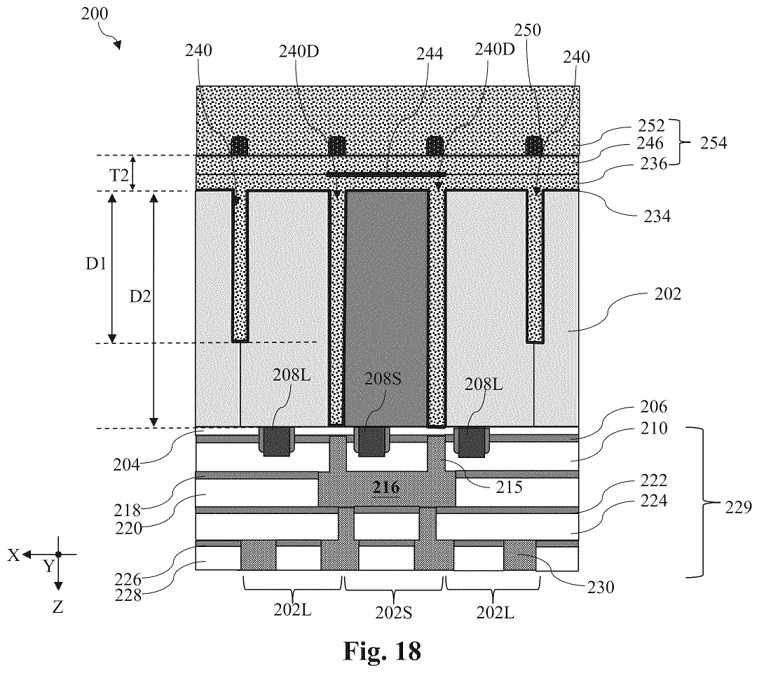

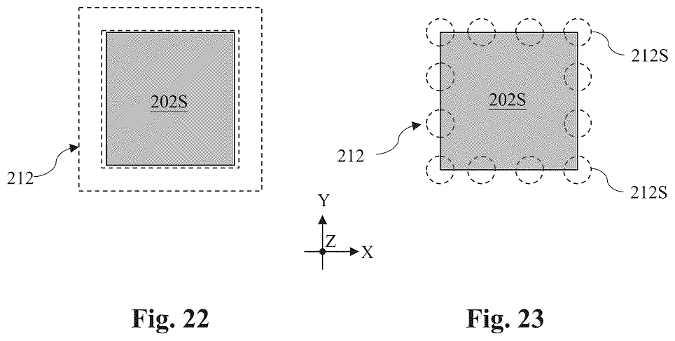

Referring to FIGS. 1 and 3, method 100 includes a block 104 where at least one opening 212 is formed in a first ILD layer 210 over the workpiece 200. At block 104, photolithography processes and etch processes are used to form the at least one opening 212. In an example process, a photoresist layer is deposited over the workpiece 200. The photoresist layer undergoes a pre-exposure baking process, exposure to radiation reflected from or transmitted through a photomask, a post-exposure baking process, and developing process, so as to form a patterned photoresist layer. The patterned photoresist layer is then applied as an etch mask to etch the at least one opening 212 in the first ILD layer 210. The etching of the first ILD layer 210 may be performed using a dry etch process that includes use of an inert gas (e.g., Ar) a fluorine-containing gas (e.g., CF₄, C₂F₆, SF₆ or NF₃), other suitable gases and/or plasmas, and/or combinations thereof. The at least one opening 212 extends around or is arranged to extend around a vertical projection area of an SPD region 202S. The at least one opening 212 may have different shapes and configurations. In some embodiments represented in FIG. 18, the at least one opening 212 may be a single continuous opening that extends completely around the vertical projection area of the SPD region 202S. The single continuous opening 212 in FIG. 22 resembles a trench with a trench width between about 0.05 μm and about 0.2 μm. Because the single continuous opening 212 extends completely around the vertical projection area of the SPD region 202S, it can be said to be ring-shaped. In some other embodiments represented in FIG. 23, the at least one opening 212 in FIG. 3 includes a plurality of separate openings 212S that are arranged along edges of the vertical protection area of the SPD region 202S. The plurality of separate openings 212S may be spaced apart from one another by a predetermined spacing and are not in fluid communication with one another. Each of the plurality of separate openings 212S may be substantially circular and have a diameter between about 0.05 μm and about 0.2 μm. The spacing between adjacent ones of the separate openings 212S may be between about 0.11 μm and about 0.5 μm. Referring back to FIG. 3, on the X-Y plane, the at least one opening 212 surrounds the SPD transistor 208S. It is noted that along the Z direction, the at least one opening 212 is substantially aligned with the boundaries between the SPD region 202S and neighboring LPD regions 202L. In some embodiments, the at least one opening 212 extends through the first ILD layer 210 and the first etch stop layer 206. In some implementations, the at least one opening 212 may partially extend into the isolation feature 204.

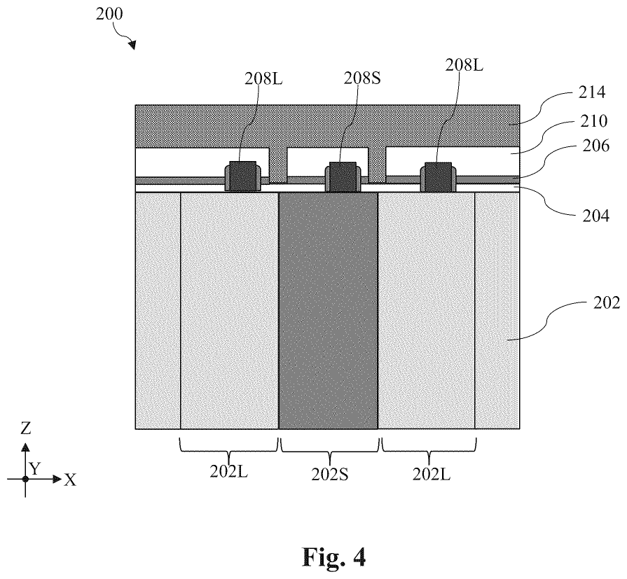

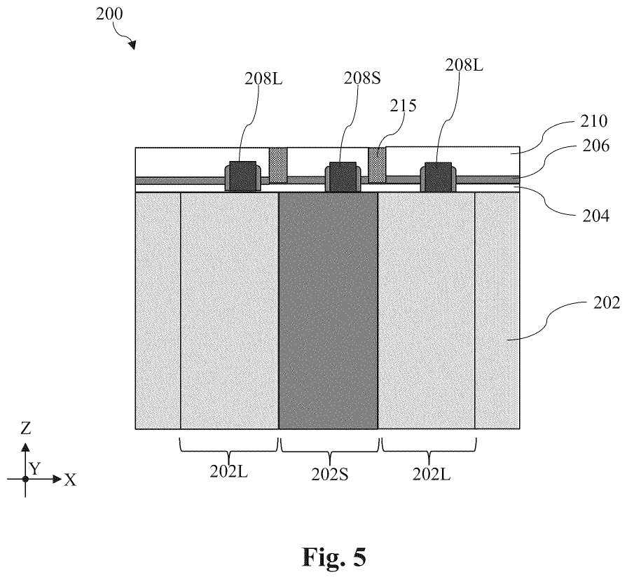

Referring to FIGS. 1, 4 and 5, method 100 includes a block 106 where a metal absorber feature 215 is formed in the at least one opening 212. To form the metal absorber feature 215, a metal fill layer 214 is first deposited over the workpiece 200, as shown in FIG. 4, and the at least one opening 212 and then excess metal fill layer 214 over the dielectric layer 210 is removed by a planarization process, such as a chemical mechanical polishing (CMP) process, as shown in FIG. 5. The metal fill layer 214 may include copper (Cu), aluminum-copper (AlCu), tungsten (W), or a suitable metal or metal alloy. The metal fill layer 214 may be deposited using physical vapor deposition (PVD) or electroplating. When the metal fill layer 214 is formed using electroplating, a seed layer is first deposited over the at least one opening 212 using CVD. After the deposition of the seed layer, the metal fill layer 214 is deposited using electroplating. The seed layer may include copper (Cu) or titanium (Ti). In some embodiments depicted in FIG. 4, the metal fill layer 214 not only fills the at least one opening 212 but also is deposited on top surfaces of the first ILD layer 210. The workpiece 200 is then planarized to remove the excess metal fill layer 214 to form the metal absorber feature 215. As the at least opening 212 may be a single continuous opening 212 (shown in FIG. 22) or a plurality of separate openings 212S (shown in FIG. 23) in different embodiment, the metal absorber feature 215 may be a single continuous metal construction or may include an array of post-like separate metal absorber features.

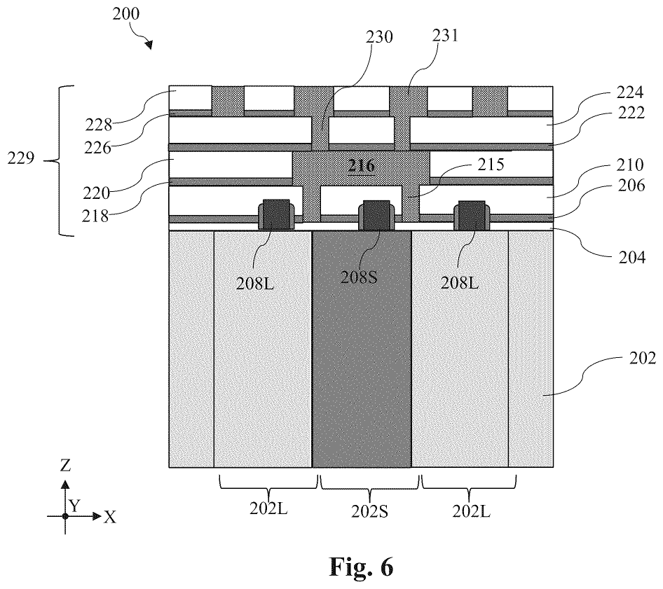

Referring to FIGS. 1 and 6, method 100 includes a block 108 where a protective metal layer 216 is formed directly over the SPD region 202S. To form the protective metal layer 216, a second etch stop layer 218 and a second ILD layer 220 are sequentially deposited over the first ILD layer 210. The second etch stop layer 218 may be similar to the first etch stop layer 206 in terms of compositions and formation processes. The second ILD layer 220 may be similar to the first ILD layer 210 in terms of compositions and formation processes. An opening for the protective metal layer 216 is formed through the second etch stop layer 218 and the second ILD layer 220. A metal fill layer is then deposited in the opening. After excess metal fill layer is removed by a planarization process, the protective metal layer 216 is formed in the second etch stop layer 218 and the second ILD layer 220. The metal fill layer for the protective metal layer 216 may include copper (Cu), aluminum-copper (AlCu), tungsten (W), or a suitable metal or metal alloy. The protective metal layer 216 functions to reduce light noise from entering into the SPD region 202S, it is disposed directly over the SPD region 202S. To ensure enclosure of the SPD region 202S, the protective metal layer 216 may be larger than the vertical projection area of the SPD region 202S. In embodiments where both the protective metal layer 216 and the SPD regions 202S are substantially square when viewed along the Z direction, the protective metal layer 216 can be made larger than the vertical projection area of the SPD region 202S. However, to avoid taking too much real estate in the interconnect structure, the enclosure margin may be smaller than about 1 μm along all edges. Because electrical connection between the metal absorber feature 215 and the protective metal layer 216 is not required, the protective metal layer 216 may or may not be in direct contact with the metal absorber feature 215. When the protective metal layer 216 is insulated from the metal absorber feature 215, the opening for the protective metal layer 216 terminates in the second etch stop layer 218 such that the remaining second etch stop layer 218 spaces apart the protective metal layer 216 and the metal absorber feature 215.

Referring to FIGS. 1 and 6, method 100 includes a block 110 where further metal layers are formed over the protective metal layer 216. The formation of the metal absorber feature 215 and the protective metal layer 216 may be regarded as part of a back-end-of-line (BEOL) process to form an interconnect structure 229 to functionally interconnect various devices in the image sensor 200. Block 110 continuous the BEOL processes to form metal layer over the protective metal layer 216. Referring to FIG. 6, block 110 may deposit a third etch stop layer 222 over the second ILD layer 220 and the protective metal layer 216. Then a third ILD layer 224 is deposited over the third etch stop layer 222. More than one contact vias 230 are then formed in the third etch stop layer 222 and the third ILD layer 224 using processes similar to those used to form the metal absorber feature 215 and the protective metal layer 216. Similarly, a fourth etch stop layer 226 and a fourth ILD layer 228 are sequentially deposited over the third ILD layer 224. Then conductive lines 231 are formed in the fourth etch stop layer 226 and the fourth ILD layer 228. The contact vias 230 and the conductive lines 231 may include copper (Cu), aluminum-copper (AlCu), tungsten (W), or a suitable metal or metal alloy. The third etch stop layer 222 and the fourth etch stop layer 226 may be similar to the first etch stop layer 206. The third ILD layer 224 and the fourth ILD layer 228 may be similar to the first ILD layer 210. As will be described below, without the protective metal layer 216, light from the LPD regions 202L may be reflected by the contact vias 230 and conductive lines 231 into the SPD region 202S. For ease of reference, the BEOL features, including the ILD layers, etch stop layers, contact vias, and metal lines, may be collectively referred to as the interconnect structure 229.

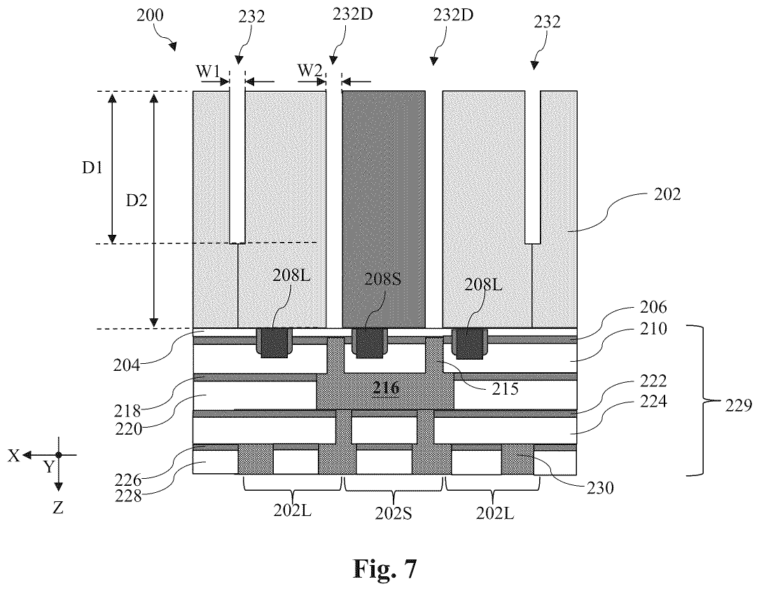

Referring to FIGS. 1 and 7, method 100 includes a block 112 where extended deep trenches 232D are formed along boundaries of the small photodiode regions. After the BEOL structures are formed, the workpiece 200 is flipped upside-down such that the substrate 202 is on top and the BEOL structures are on bottom. To indicate the flipping of the workpiece 200, the Z-direction arrow in FIG. 7 now points downwards. To flip the workpiece 200 upside-down, a carrier substrate (not explicitly shown) is bonded to the substrate 202. In some embodiments, the carrier substrate may be bonded to the workpiece 200 by fusion bonding, by use of an adhesion layer, or a combination thereof. In some instances, the carrier substrate may be formed of semiconductor materials (such as silicon), sapphire, glass, polymeric materials, or other suitable materials. In embodiments where fusion bonding is used, the carrier substrate includes a first oxide layer and the workpiece 200 includes a second oxide layer. After both the first oxide layer and the second oxide layer are treated, they are placed in plush contact with one another for direct bonding at room temperature or at an elevated temperature. Once the carrier substrate is bonded to the workpiece 200, the workpiece 200 is flipped over, as shown in FIG. 6.

After the workpiece 200 is flipped upside-down, deep trenches 232 and extended deep trenches 232D are formed in the substrate 202. As shown in FIG. 7, the deep trenches 232 are formed between two adjacent LPD regions 202L and the extended deep trenches 232D are formed at boundaries of an SPD region 202S and an LPD region 202L. As the names suggest, the extended deep trenches 232D extend deeper into the substrate 202. As shown in FIG. 7, the deep trenches 232 have a first depth D1 and the extended deep trenches 232D have a second depth D2. The second depth D2 is greater than the first depth D1. In some instances, the first depth D1 is between about 1.0 μm and about 9 μm, and the second depth D2 is between about 1.5 μm and about 10 μm. A ratio of the first depth D1 to the second depth D2 may be between about 55% and about 90%. Etching of the extended deep trenches 232D also result in a greater trench width. As illustrated in FIG. 7, each of the deep trenches 232 may include a first trench width W1 and each of the extended deep trenches 232D may include a second trench width W2. The second trench width W2 is greater than the first trench width W1. In some instances, the first trench width W1 may be between about 10 nm and about 300 nm and the second trench width W2 may be about 110% to about 200% of the first trench width W1.

In an example process, a hard mask (not explicitly shown) is formed over the substrate 202. The hard mask may be a single layer or a multi-layer. In one embodiment, the hard mask may include a silicon nitride layer and a silicon oxide layer over the silicon nitride layer. Photolithography processes and etch processes are then performed to pattern the hard mask. For example, a photoresist layer (not explicitly shown) is formed over the hard mask, exposed to a suitable photolithography radiation source, and developed to form a patterned photoresist layer. The patterned photoresist layer is then used as an etch mask to pattern the hard mask. The substrate 202 is then anisotropically etched using the patterned hard mask as an etch mask, thereby forming the deep trenches 232. The anisotropic etch may be a dry etch process that implements sulfur hexafluoride (SF₆), carbon tetrafluoride (CF₄), nitrogen trifluoride (NF₃), other fluorine-containing gas, oxygen (O₂), or a mixture thereof. After the deep trenches 232 are formed, another pattern film or another patterned photoresist layer is formed over the workpiece 200 to selectively exposes the deep trenches 232 along boundaries of the SPD regions 202S. The deep trenches 232 along boundaries of the SPD regions 202S are then etched to further extend into the substrate 202 so as to form the extended deep trenches 232D.

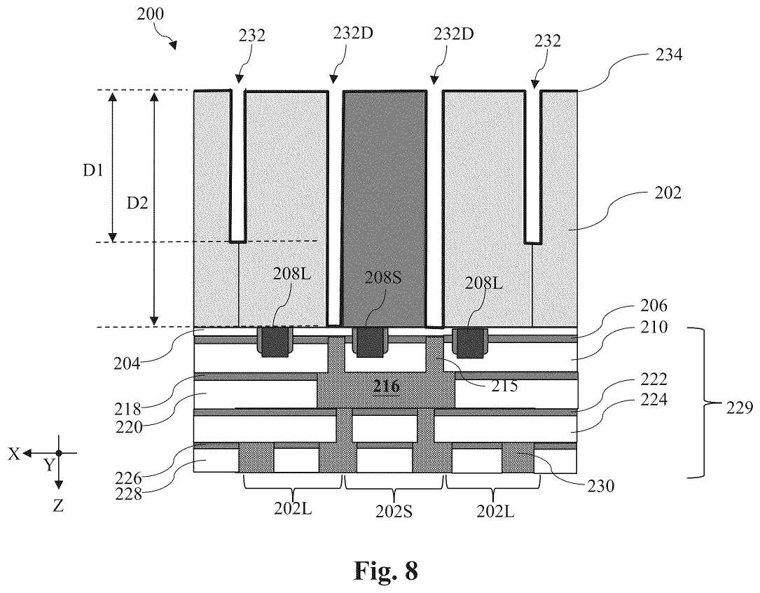

Referring to FIGS. 1 and 8, method 100 includes a block 114 where a liner 234 is conformally deposited over the workpiece 200, including the deep trenches 232 and the extended deep trenches 232D. The liner 234 may include a metal. In some embodiments, the liner 234 includes aluminum (Al), tungsten (W), ruthenium (Ru), cobalt (Co), or copper (Cu). The liner 234 may be deposited using CVD or ALD.

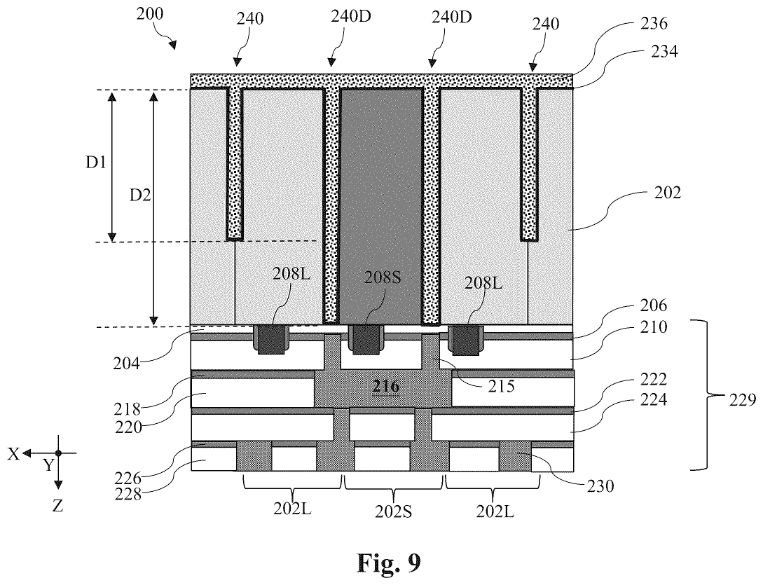

Referring to FIGS. 1 and 9, method 100 includes a block 116 where a fill material 236 is deposited in the deep trenches 232 and the extended deep trenches 232D to form deep trench isolation (DTI) features 240 and extended DTI features 240D. The fill material 236 may include a dielectric layer, such as a semiconductor oxide or a metal oxide. For example, the fill material 236 may include silicon oxide, aluminum oxide, hafnium oxide, titanium oxide, barium titanate, zirconium oxide, lanthanum oxide, barium oxide, strontium oxide, yttrium oxide, or a combination thereof. In one embodiment, the fill material 236 includes silicon oxide. The fill material 236 may be deposited using atomic layer deposition (ALD) or chemical vapor deposition (CVD). The deposition of the fill material 236 into the deep trenches 232 and the extended deep trenches 232D form the DTI features 240 and extended DTI features 240D, respectively. Generally, the DTI features 240 and the extended DTI features 240D may function as a reflector to reflect light toward the SPD regions 202S and LPD regions 202L to increase quantum efficiency (QE). In other words, the DTI features 240 and the extended DTI features 240D may allow incident light to bounce around in the SPD regions 202S and LPD regions 202L before the incident light is dissipated, absorbed, or escapes.

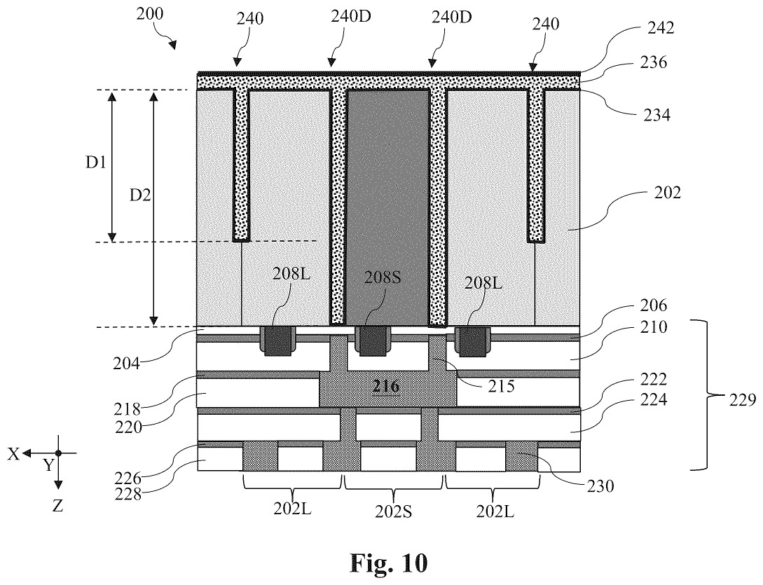

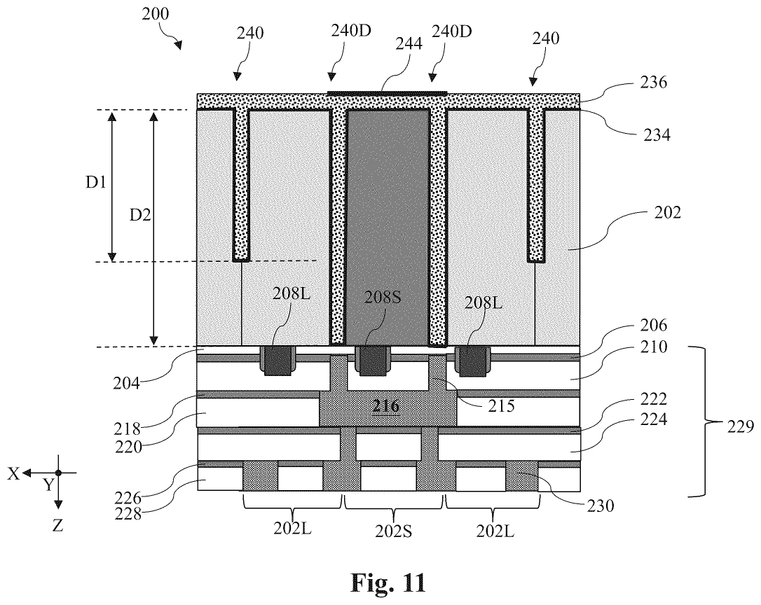

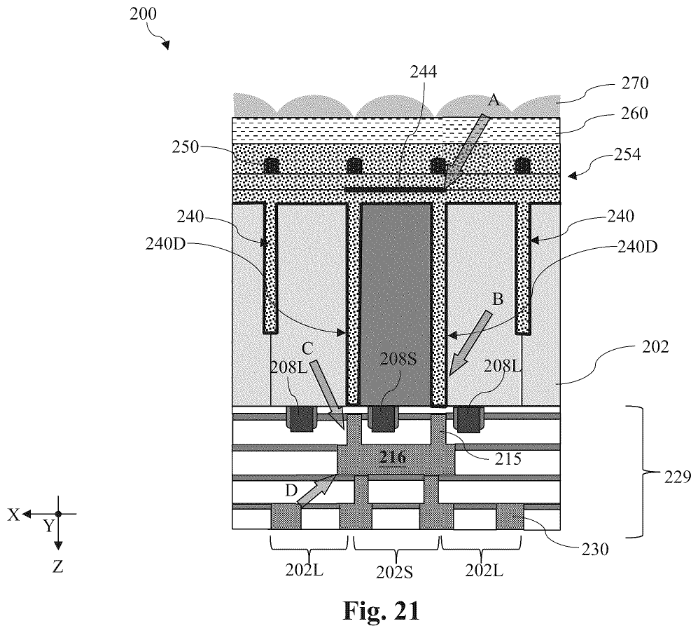

Referring to FIGS. 1, 10 and 11, method 100 includes a block 118 where a metal film 244 is deposited over the fill material 236. The metal film 244 is formed directly over the SPD region 202S (or directly below as the workpiece 200 is flipped upside-down) to diffract or deflect angled incident light from over the neighboring LPD regions 202L. In an example process illustrated in FIGS. 10 and 11, a global metal layer 242 is blanketly deposited over the fill material 236 to a thickness between about 100 Å and about 1000 Å, as shown in FIG. 10. The global metal layer 242 may include tin (Sn), aluminum-copper (AlCu), or tungsten (W). The deposited global metal layer 242 is then patterned to form the metal film 244, as shown in FIG. 11. As shown in FIG. 11, the metal film 244 is directly over the SPD region 202S and the extended DTI feature 240D around the SPD region 202S such that the metal film 244 overlaps with vertical projection areas of the SPD region 202S and the extended DTI feature 240D. As will be described further in conjunction with FIGS. 21, 22 and 23, the extended DTI feature 240D may extend completely around a single SPD region 202S or an array of multiple SPD regions 202S. Accordingly to the present disclosure, extended DTI features 240D are founded along boundaries between an SPD region 202S and a bordering LPD regions 202L. In at least some of the embodiments, the metal film 244 reduces the quantum efficiency (QE) of the SPD region 202S and is at least one of the reasons why the SPD region 202S has a lower QE than the LPD regions 202L. Other reasons may have to do with the dimensions of the SPD region 202S and the LPD regions 202L.

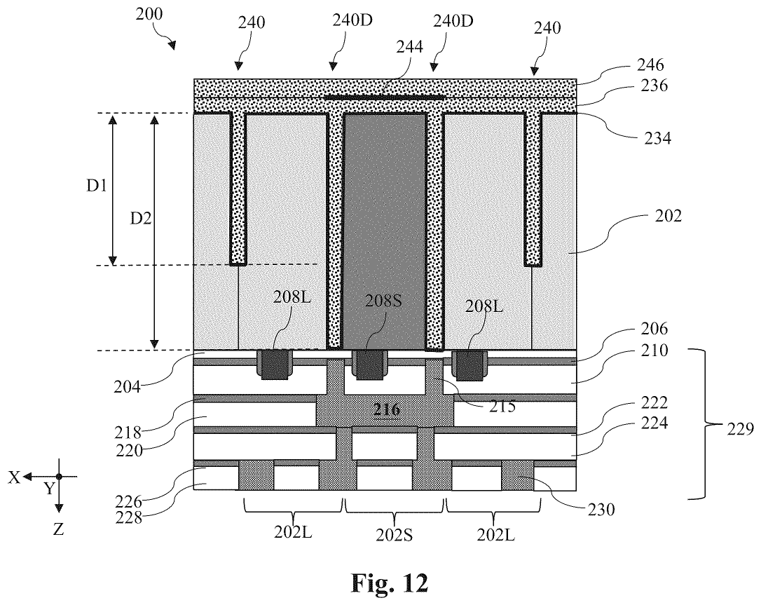

Referring to FIGS. 1 and 12, method 100 includes a block 120 where a first passivation layer 246 is formed over the metal film 244. The first passivation layer 246 may include silicon oxide and may be deposited over the workpiece 200 using CVD. The first passivation layer 246 may share the same composition with the fill material 236.

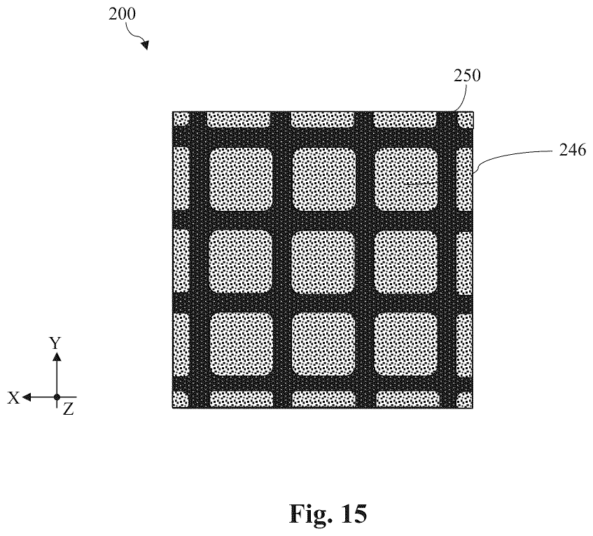

Referring to FIGS. 1, 13 and 14, method 100 includes a block 122 where a metal grid 250 is formed over the first passivation layer 246. As its name suggests, the metal grid 250 is a grid-like structure or framework that extends over several, if not all, of the SPD regions 202S and the LPD regions 202L. More specifically, the metal grid 250 corresponds to boundaries of SPD regions 202S and the LPD regions 202L to define light passage openings to the SPD regions 202S and the LPD regions 202L. In some embodiments, the metal grid 250 may include tin (Sn), aluminum-copper (AlCu), aluminum (Al), tungsten (W), ruthenium (Ru), cobalt (Co), or copper (Cu). In one embodiment, the metal grid 250 is formed of tin (Sn). The metal grid 250 may physically block light reflection among adjacent photodiode regions (i.e., SPD regions 202S and LPD regions 202L) and prevent cross-talk among neighboring photodiodes. In an example process to form the metal grid 250, a metal layer is deposited over the first passivation layer 246. Then photolithography process and etch processes are used to pattern the metal layer into the metal grid 250. In the depicted embodiment, the metal grid 250 has chamfered or rounded top corners due to etching aspect in the formation process. As shown in a top view of the workpiece 200 shown in FIG. 15, due to the etching aspect of its formation process, the metal grid 250 may form squircle grid openings, rather than sharp square openings. As used herein, a squircle grid opening refers to a substantially square grid opening with rounded corners.

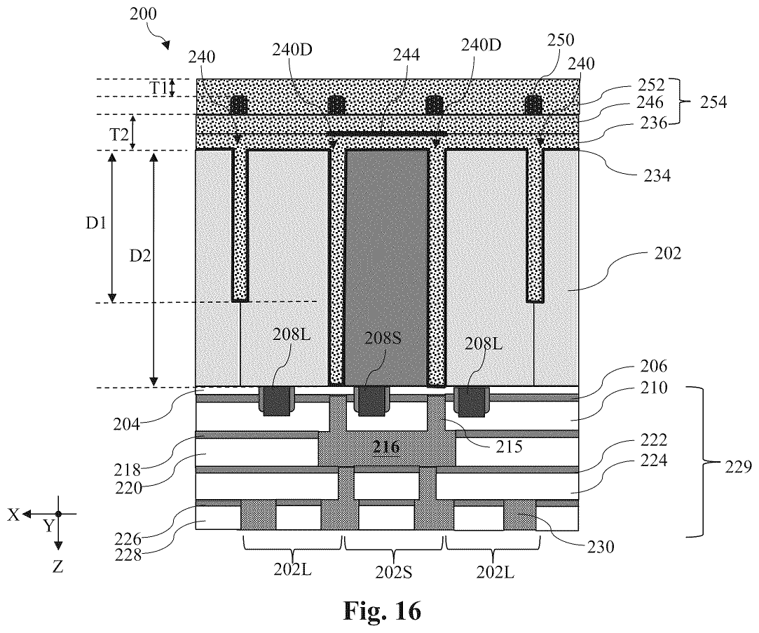

Referring to FIGS. 1 and 16, method 100 includes a block 124 where a second passivation layer 252 is deposited over the metal grid 250. Like the first passivation layer 246, the second passivation layer 252 may include silicon oxide and may be deposited using CVD. The portion of the fill material 236 over the SPD region 202S and the LPD regions 202L, the first passivation layer 246 and the second passivation layer 252 may be collectively regarded as a passivation structure. The metal grid 250 and the metal film 244 are embedded in such a passivation structure. According to the present disclosure, a thickness of the passivation structure is minimized to reduce paths of light noises from over the LPD regions 202L to the SPD regions 202S. Referring to FIG. 16, the passivation structure includes a top thickness T1 measured from a top surface of the metal grid 250 and a bottom thickness T2 measured from a bottom surface of the metal grid to a top surface of the substrate 202. The top thickness T1 represents a top gap that is not blocked by the metal grid 250 and the bottom thickness T2 represents a bottom gap that is not blocked by the metal grid 250. In some embodiments, the top thickness T1 and the bottom thickness T2 may each be between about 100 Å and about 1000 Å.

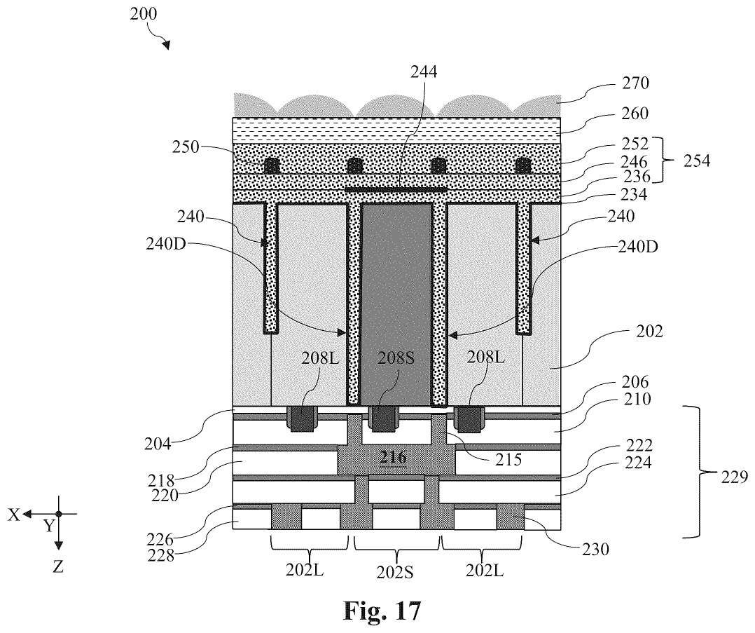

Referring to FIGS. 1 and 17, method 100 includes a block 126 where further processes are performed. Such further processes may include formation of a color filter array 260 over the second passivation layer 252 and formation of microlens features 270 over the color filter array 260. The color filter array 260 may be formed of a polymeric material or a resin that includes color pigments. At block 126, the color filter array 260 is formed over the second passivation layer 252. The color filter array 260 includes a plurality of filters each allowing for the transmission of radiation (e.g., light) having a specific range of wavelength, while blocking light of wavelengths outside of the specified range. Referring still to FIG. 17, microlens features 270 are formed over the color filter array 260. The microlens features 270 may be formed of any material that may be patterned and formed into lenses, such as a high transmittance acrylic polymer. In an embodiment, a microlens layer may be formed using a material in a liquid state and spin-on techniques. This method has been found to produce a substantially planar surface and a microlens layer having a substantially uniform thickness, thereby providing greater uniformity in the microlens features 270. Other methods, such as CVD, PVD, or the like, may also be used. The planar material for the microlens layer may be patterned using a photolithography and etch technique to pattern the planar material in an array of microlens features 270 corresponding to the array of the photodiode regions (i.e., SPD regions 202S and LPD regions 202L). The planar material may then be reflowed to form an appropriate curved surface for the microlens features 270. The microlens features 270 may be cured using an ultraviolet (UV) treatment.

Upon conclusion of operations at block 126, an image sensor 200 shown in FIG. 17 is substantially formed. As a convention in the industry, the side of the substrate 202 on which the LPD transistors 208L and SPD transistor 208S are formed is referred to as the front side while the opposing side on which the passivation structure 254 is formed is referred as the back side. Because the image sensor 200 allows incident light coming from the back side, the image sensor 200 in FIG. 17 includes a backside illumination (BSI) structure and may be referred to as a BSI image sensor 200.

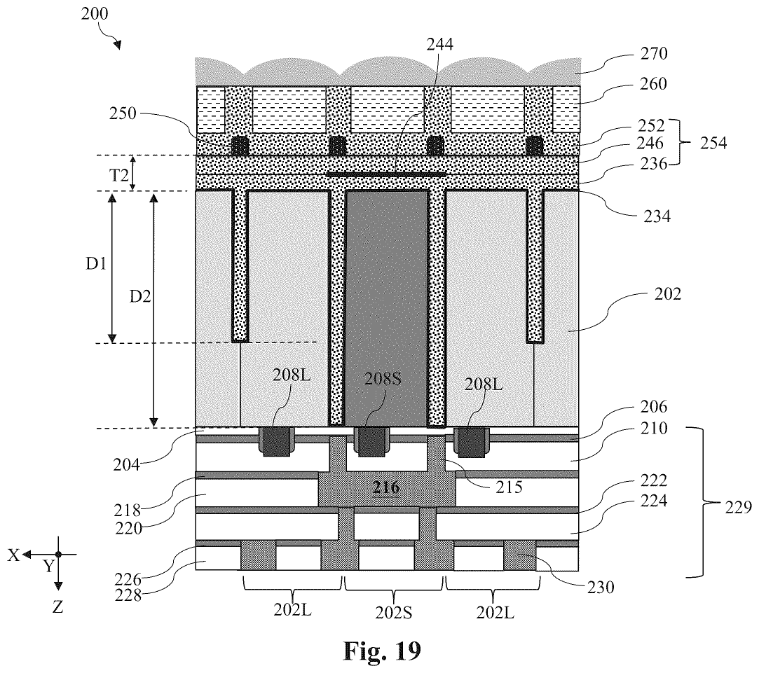

In some alternative embodiments, the color filter array 260 is partially embedded in the passivation structure 254 rather than being disposed completely over the passivation structure 254. Reference is first made to FIG. 18. In these alternative embodiments, the second passivation layer 252 is formed to a greater thickness than the counterpart in FIG. 16. The thicker second passivation layer 252 in FIG. 18 is then patterned to form color filter openings. Color filter elements are then formed into these color filter openings to form the color filter array 260. Different from the color filter array in FIG. 17, the color filter elements in the color filter array shown in FIG. 19 are separated from one another by the second passivation layer 252.

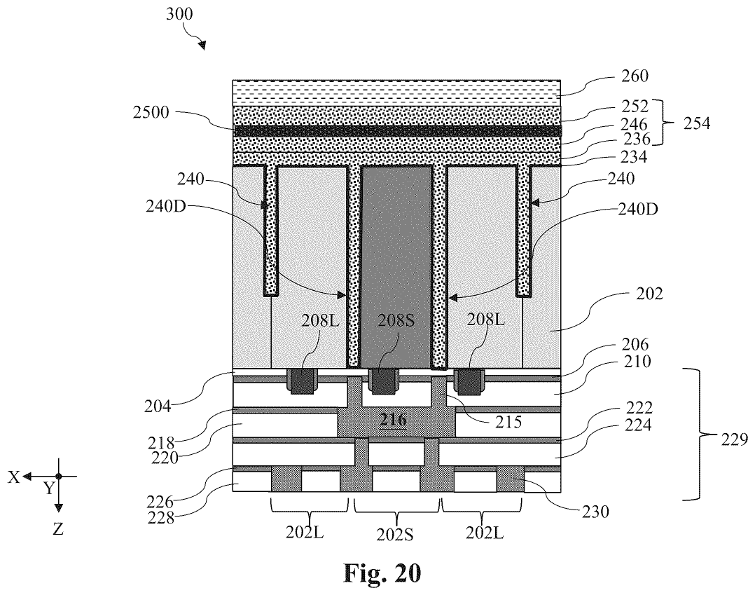

The BSI image sensor 200 shown in FIG. 17 may be disposed in a pixel area surrounded by a peripheral area. As their names suggest, the pixel area includes the BSI image sensor 200 that are shone upon by incident light while the peripheral area includes reference structures that are not shone upon. FIG. 20 illustrates an example reference structure 300. Different from the BSI image sensor 200 in FIG. 17, the reference structure 300 includes a metal shield 2500. Having no grid openings like the metal grid 250, the metal shield 2500 functions to block off incident light from. In some implementations, the metal shield 2500 over the reference structure 300 and the metal grid 250 over the BSI image sensor 200 are formed simultaneously using the same material. In an example process, a metal layer is deposited over the pixel area and the peripheral area and then only the metal layer in the pixel area undergoes the patterning process to form the metal grid 250. In the implementations, the metal shield 2500 and the metal grid 250 may have the same thickness along the Z direction. The thickness of the metal shield 2500 is greater than that of the metal film 244. In the depicted embodiments, because the incident light to the peripheral area is completely blocked off by the metal shield 2500, the reference structure 300 does not include metal film 244. The reference structure 300 functions to provide a background level for a black state. The background level from the reference structure 300 allows for black level correction (BLC), which boosts sensitivity.

FIG. 21 illustrates how the thinner passivation structure, the metal film 244, the extended DTI features 240D, the metal absorber feature 215, and the protective metal layer 216 operate to reduce the stray light noise from the LPD regions 202L to the SPD regions 202S. Incident light A represents light transmitting through and/or refracted by the color filter array 260 and the microlens features 270 from over a LPD region 202L. FIG. 21 schematically shows that incident light A, while coming in at an angle, is blocked or reflected by the metal film 244. It is noted that the thinner passivation structure 254 may also play a role here. When the top gap (above the metal grid 250) and the bottom gap (below the metal grid 250) is too large, incident light A with a shallow angle (i.e., having a near 90° incident angle relative to a normal direction of the image sensor 200) may avoid the metal film 244 and enter the SPD region 202S. Incident light B represents light reflected by the liner 234 of the DTI feature 240 around an LPD region 202L. Because the extended DTI feature 240D extends substantially through the substrate 202, the extended DTI feature 240 manages to block or reflect incident light B, preventing it from entering the SPD region 202S. Incident light B reflected by the extended DTI feature 240D may generate more photon electrons in the LPD region 202L, increasing its quantum efficiency.

Reference is still made to FIG. 21. Incident light C represents light that light that penetrates an LPD region 202L and enters into the interconnect structure 229. Without the metal absorber feature 215 and the protective metal layer 216, incident light C may be reflected by metal features in the interconnect structure 229 and becomes noise for the SPD region 202S. As representatively shown in FIG. 21, the metal absorber feature 215 blocks and reflects the incident light C. Incident light D represents light reflected by metal features in the interconnect structure 229. Incident light D may originate from light similar to incident light C but it may not originate from an adjacent LPD region 202L like incident light C. As shown in FIG. 21, the protective metal layer 216 functions to block and reflect incident light D.

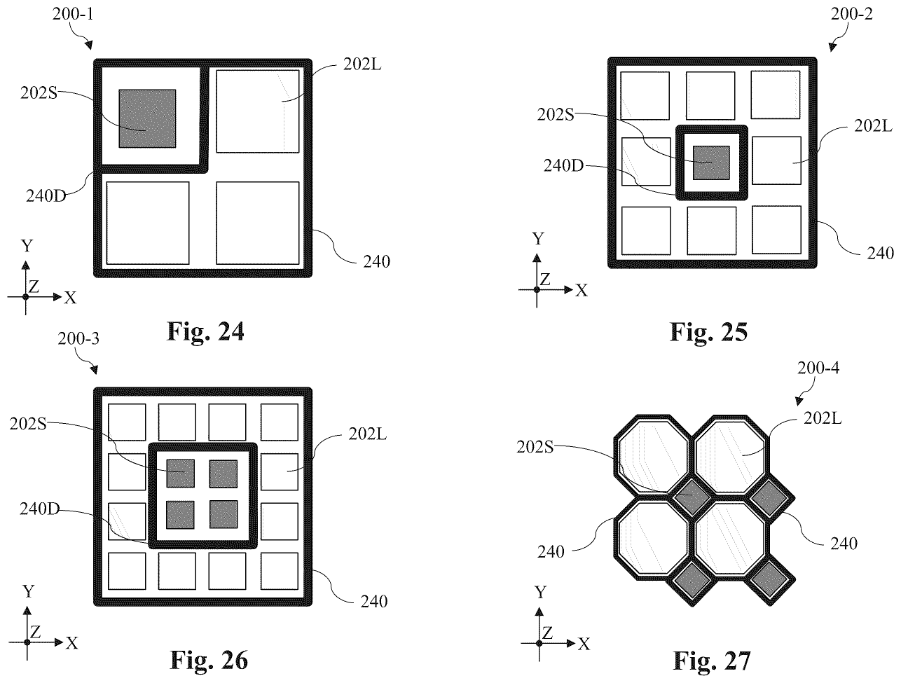

While the SPD region 202S is shown to be sandwiched between two LPD regions 202L in FIGS. 2-20. The present disclosure is not so limited and should be understood to include other designs where at least one SPD region 202S is bordering an LPD region 202L. Example designs of an image sensor 200 according to the present disclosure are illustrated in FIGS. 24, 25, 26, and 27. FIG. 24 illustrates a schematic top view of a first image sensor 200-1 that includes one SPD region 202S and three LPD regions 202L arranged in a rectangle. The SPD region 202S is disposed on the left top corner of the rectangle and the three LPD regions 202L occupy the other three corners. In the embodiments represented in FIG. 24, the SPD region 202S is isolated from the LPD regions 202L by the extended DTI feature 240D while the LPD regions 202L are not spaced apart from one another by any DTI feature 240 or extended DTI feature 240D. Rather, the first image sensor 200-1, including the SPD region 202S and the three LPD regions 202L, is surrounded by a DTI feature 240.

FIG. 25 illustrates a schematic top view of a second image sensor 200-2 that includes one SPD region 202S and eight (8) LPD regions 202L arranged in a rectangle to surround the SPD region. The SPD region 202S is disposed at a geographic center of the rectangle and the eight (8) LPD regions 202L are disposed along edges to go around the SPD region 202S. In the embodiments represented in FIG. 25, the SPD region 202S is isolated from the eight (8) LPD regions 202L by the extended DTI feature 240D while the eight (8) LPD regions 202L are not spaced apart from one another by any DTI feature 240 or extended DTI feature 240D. Rather, the second image sensor 200-2, including the SPD region 202S and the eight LPD regions 202L, is surrounded by a DTI feature 240.

FIG. 26 illustrates a schematic top view of a third image sensor 200-3 that includes four (4) SPD region 202S and twelve (12) LPD regions 202L arranged in a rectangle. The four (4) SPD region 202S are disposed at a geographic center of the rectangle and the twelve (12) LPD regions 202L are disposed along edges to go around the four (4) center SPD regions 202S. In the embodiments represented in FIG. 26, the four (4) SPD region 202S are isolated from the twelve (12) LPD regions 202L by the extended DTI feature 240D while the LPD regions 202L are not spaced apart from one another by any DTI feature 240 or extended DTI feature 240D. Additionally, the four (4) SPD regions 202S are not isolated from one another by any DTI features 240 or the extended DTI features 240D. Rather, the third image sensor 200-3, including the four (4) SPD region 202S and the twelve (12) LPD regions 202L, is surrounded by a DTI feature 240.

FIG. 27 illustrates a schematic top view of a fourth image sensor 200-4 that includes octagonal LPD regions 202L and SPD regions 202S disposed in interstitial spaces of the octagonal LPD regions 202L. Each of the SPD regions 202S may have a square shape or a rectangular shape. Each of the SPD regions 202S is surrounded by an extended DTI feature 240D. Except for the bordering edge with an SPD region 202S, each of the LPD regions 202L is surrounded by a DTI feature 240. That is, each of the LPD regions 202L is surrounded by an DTI feature 240 and an extended DTI feature 240D.

Thus, in some embodiments, the present disclosure provides an image sensor. The image sensor includes a first photodiode disposed between a second photodiode and a third photodiode along a direction, a first deep trench isolation (DTI) feature disposed between the first photodiode and the second photodiode, and a second DTI feature disposed between the first photodiode and the third photodiode. A depth of the first DTI feature is greater than a depth of the second DTI feature and a quantum efficiency of the second photodiode is smaller than a quantum efficiency of the first photodiode.

In some embodiments, a quantum efficiency of the third photodiode is substantially the same as the quantum efficiency of the first photodiode. In some implementations, the first photodiode has a first width along the direction, the second photodiode has a second width along the direction, and the first width is greater than the second width. In some instances, the image sensor may further include a passivation layer disposed over the first photodiode, the second photodiode and the third photodiode, and a metal grid embedded in the passivation layer and spanning over the first photodiode, the second photodiode and the third photodiode. In some embodiments, the image sensor further includes a metal film embedded in the passivation layer and disposed between the metal grid and the second photodiode. In some implementations, the image sensor further includes a first dielectric layer disposed below the first photodiode, the second photodiode and the third photodiode, and a first metal structure embedded in the first dielectric layer. The first metal structure is substantially aligned with the first DTI feature along a vertical direction. In some embodiments, the first metal structure has a ring shape and extends completely around a portion of the first dielectric layer directly below the second photodiode. In some instances, the image sensor further includes a second dielectric layer disposed below the first dielectric layer, and a second metal structure embedded in the second dielectric layer and disposed directly over the second photodiode. The first metal structure is in direct contact with the second metal structure. In some embodiments, the first metal structure includes an array of metal posts.

Another aspect of the present disclosure involves an image sensor. The image sensor includes a first photodiode, a second photodiode adjacent the first photodiode along a direction, a first passivation layer disposed over the first photodiode and the second photodiode, a metal grid disposed over the first passivation layer, and a metal film embedded in the first passivation layer, the metal film disposed directly over the first photodiode but not extending over the second photodiode. A quantum efficiency of the first photodiode is different from a quantum efficiency of the second photodiode.

In some embodiments, the quantum efficiency of the first photodiode is smaller than the quantum efficiency of the second photodiode. In some implementations, the first photodiode has a first width along the direction, the second photodiode has a second width along the direction, and the first width is smaller than the second width. In some implementations, the image sensor includes a first deep trench isolation (DTI) feature around the first photodiode and a second DTI feature along a sidewall of the second photodiode. A depth of the first DTI feature is greater than a depth of the second DTI feature. In some embodiments, the metal film includes tin, aluminum copper, or tungsten. In some embodiments, the image sensor further includes a second passivation layer disposed over the first passivation layer and the metal grid, a first color filter element embedded in the second passivation layer and disposed directly over the first photodiode, and a second color filter element embedded in the second passivation layer and disposed directly over the second photodiode. the first color filter element and the second color filter element are spaced apart by a portion of the second passivation layer. In some embodiments, the first passivation layer includes a thickness and the thickness is between about 100 Å and about 1000 Å.

Yet another aspect of the present disclosure involves a method. The method includes receiving a substrate that includes a first photodiode region disposed between a second photodiode region and a third photodiode region along a direction, a first transistor disposed over the first photodiode region, a second transistor disposed over the second photodiode region, a third transistor disposed over the third photodiode region, and a first dielectric layer over the first transistor, the second transistor and the third transistor. The method further includes forming a ring-shaped trench in the first dielectric layer such that the ring-shaped trench extends completely around the second transistor, and depositing a first metal fill layer in the ring-shaped trench to form a first metal structure. A first portion of the first metal structure is vertically aligned with an interface between the first photodiode region and the second photodiode region and a second portion of the first metal structure is vertically aligned with an interface between the second photodiode region and the third photodiode region.

In some embodiments, the method further includes depositing a second dielectric layer over the first dielectric layer and the first metal structure, forming an opening in the second dielectric layer such that the opening is substantially aligned with a vertical projection area of the second photodiode region, and depositing a second metal fill layer in the opening to form a second metal feature. In some implementations, the method further includes flipping over the substrate, and forming a deep trench completely around the second photodiode region such that the first photodiode region and the third photodiode region are spaced apart from the second photodiode region by the deep trench along the direction. The deep trench substantially extends through an entire height of the second photodiode region. In some instances, the method further includes conformally depositing a liner over the deep trench, and after the conformally depositing of the liner, depositing a dielectric material over the deep trench.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. A method, comprising:
forming a structure comprising:
a substrate comprising a first photodiode region, a second photodiode region and a third photodiode region, the substrate comprising a frontside surface and a backside surface,
an isolation feature over the frontside surface of the substrate,
a first etch stop layer (ESL) over the isolation feature, and
a first interlayer dielectric (ILD) layer over the ESL;
forming a ring-shaped trench through the first ILD layer and the first ESL such that the ring-shaped trench surrounds a vertical projection area of the second photodiode region; and
depositing a first metal fill layer over the ring-shaped trench and the first ILD layer;
planarizing the first metal fill layer to expose the first ILD layer and form a first metal structure,
depositing a second ESL over the first metal structure and the first ILD layer;
depositing a second ILD layer over the second ESL; and
forming a second metal structure in the second ESL and the second ILD layer such that the second metal structure interfaces the first metal structure.

2. The method of claim 1,
wherein the structure further comprises a transistor over the second photodiode region,
wherein the first metal structure surrounds the transistor.

3. The method of claim 1, wherein the first metal structure and the second metal structure comprise copper, aluminum-copper, or tungsten.

4. The method of claim 1, wherein an area of the second metal structure is greater than the vertical projection area of the second photodiode region.

5. The method of claim 1, wherein the vertical projection area is square in shape.

6. The method of claim 1, further comprising:
forming a deep trench from the backside surface of the substrate, the deep trench being completely around the second photodiode region such that the first photodiode region and the third photodiode region,
wherein the deep trench substantially extends through an entire height of the second photodiode region.

7. The method of claim 6, further comprising:
conformally depositing a liner over the deep trench;
after the conformally depositing of the liner, depositing a dielectric material over the deep trench;
depositing a global metal layer over the dielectric material;
patterning the global metal layer to form a third metal structure directly over the second photodiode region;
depositing a first passivation layer over the third metal structure and the dielectric material;
forming a metal grid over the first passivation layer;
forming a second passivation layer over the metal grid;
forming a color filter array over the second passivation layer; and
forming microlens features over the color filter array.

8. The method of claim 7, wherein the liner comprises a metal.

9. The method of claim 7, wherein the first passivation layer and the second passivation layer comprise silicon oxide.

10. The method of claim 7, wherein the dielectric material comprises silicon oxide, aluminum oxide, hafnium oxide, titanium oxide, barium titanate, zirconium oxide, lanthanum oxide, barium oxide, strontium oxide, yttrium oxide, or a combination thereof.

11. A method, comprising:
forming a structure comprising:
a substrate comprising a first photodiode region, a second photodiode region and a third photodiode region, the substrate comprising a frontside surface and a backside surface,
an isolation feature over the frontside surface of the substrate,
a first etch stop layer (ESL) over the isolation feature, and
a first interlayer dielectric (ILD) layer over the ESL;
forming a ring-shaped trench through the first ILD layer and the first ESL such that the ring-shaped trench surrounds a vertical projection area of the second photodiode region; and
depositing a first metal fill layer over the ring-shaped trench and the first ILD layer;
planarizing the first metal fill layer to expose the first ILD layer and form a first metal structure,
depositing a second ESL over the first metal structure and the first ILD layer;
depositing a second ILD layer over the second ESL;
forming a second metal structure in the second ESL and the second ILD layer such that the second metal structure interfaces the first metal structure,
forming a deep trench from the backside surface of the substrate, the deep trench being completely around the second photodiode region such that the first photodiode region and the third photodiode region,
conformally depositing a liner over the deep trench;
after the conformally depositing of the liner, depositing a dielectric material over the deep trench;
depositing a global metal layer over the dielectric material; and
patterning the global metal layer to form a third metal structure directly over the second photodiode region.

12. The method of claim 11, wherein the deep trench substantially extends through an entire height of the second photodiode region.

13. The method of claim 11, wherein the liner comprises aluminum (Al), tungsten (W), ruthenium (Ru), cobalt (Co), or copper (Cu).

14. The method of claim 11, wherein the first metal structure and the second metal structure comprise copper, aluminum-copper, or tungsten.

15. The method of claim 11, wherein the global metal layer comprises tin (Sn), aluminum-copper (AlCu), or tungsten (W).

16. The method of claim 11,
wherein an area of the second metal structure is greater than the vertical projection area of the second photodiode region,
wherein the vertical projection area is square in shape.

17. A method, comprising:
receiving a substrate comprising:
a first photodiode region disposed between a second photodiode region and a third photodiode region along a direction,
a first transistor disposed over the first photodiode region,
a second transistor disposed over the second photodiode region,
a third transistor disposed over the third photodiode region, and
a first dielectric layer over the first transistor, the second transistor and the third transistor,
forming a ring-shaped trench in the first dielectric layer such that the ring-shaped trench extends completely around the second transistor; and
depositing a first metal fill layer in the ring-shaped trench to form a first metal structure,
wherein a first portion of the first metal structure is vertically aligned with an interface between the first photodiode region and the second photodiode region and a second portion of the first metal structure is vertically aligned with an interface between the second photodiode region and the third photodiode region.

18. The method of claim 17, further comprising:
depositing a second dielectric layer over the first dielectric layer and the first metal structure;
forming an opening in the second dielectric layer such that the opening is substantially aligned with a vertical projection area of the second photodiode region; and
depositing a second metal fill layer in the opening to form a second metal feature.

19. The method of claim 17, further comprising:
flipping over the substrate; and
forming a deep trench completely around the second photodiode region such that the first photodiode region and the third photodiode region are spaced apart from the second photodiode region by the deep trench along the direction,
wherein the deep trench substantially extends through an entire height of the second photodiode region.

20. The method of claim 19, further comprising:
conformally depositing a liner over the deep trench; and
after the conformally depositing of the liner, depositing a dielectric material over the deep trench.
